(19) United States
(12) Patent Application Publication
(10) Pub. No.: US 2010/0062585 A1
(43) Pub. Date: Mar. 11, 2010

(54) METHOD FOR FORMING SILICON THIN FILM

(75) Inventor: Eiji Takahashi, Kyoto (JP)

Correspondence Address: Cheng Law Group, PLLC, 1100 17th Street, N.W., Suite 503, Washington, DC, 20036, US

(73) Assignee: NISSIN ELECTRIC CO., LTD., Kyoto-shi, Kyoto (JP)

(21) Appl. No.: 12/523,709

(22) PCT Filed: Oct. 29, 2007
(86) PCT No.: PCT/JP2007/070995

§ 371 Date: Nov. 17, 2009

(30) Foreign Application Priority Data
Jan. 19, 2007 (JP) 2007-010476

(51) Int. Cl. H01L 21/20

(52) U.S. Cl. 438/479; 257/E21.09

(57) ABSTRACT

A method for forming a silicon thin film which can form a crystalline silicon thin film relatively at a low temperature, economically and productively is provided. A method for forming a silicon thin film which can provide a substrate for thin film transistor with a lowered leakage current is provided.

Provided is a method for forming a silicon thin film in which a substrate S is exposed to plasma of a gas for hydrogen bonding process containing hydrogen, and a crystalline silicon thin film is then formed on the substrate. By employing as the substrate S a substrate in which the film formation target face is a nitrogen-containing gate insulating film formed on the substrate body, a substrate which can provide a thin film transistor having high electron mobility and low OFF-current can be obtained.

### TECHNICAL FIELD

The present invention relates to a method for forming a silicon thin film by a plasma CVD method.

### BACKGROUND ART

Silicon thin films have been conventionally employed as materials of TFT (thin film transistor) switches provided in pixels of liquid crystal display devices, or for producing various kinds of integrated circuits, solar cells and other devices.

Silicon thin films are often formed by the plasma CVD method using a silane-based reaction gas. In such a case, most of the films are amorphous silicon thin films.

An amorphous silicon thin film can be formed on a deposition target substrate at a relatively low substrate temperature, and can be readily formed over a large area in plasma of a material gas by high-frequency discharge (frequency: 13.56 MHz) using parallel plate electrodes. For this reason, amorphous silicon thin films have been widely used until now for switching devices for pixels of liquid crystal display devices, solar cells and other devices.

However, further improvement in power generation efficiency in solar cells utilizing silicon films, further improvement in response speed and other characteristics of semiconductor devices utilizing silicon films cannot be expected of such amorphous silicon films. Accordingly, use of crystalline silicon thin films (for example, polycrystalline silicon thin films) is contemplated (for example, JP2001-313257A).

For example, known methods of forming the polycrystalline silicon thin film include a method wherein a deposition target substrate is kept at a temperature of 600 to 700° C. or higher, and a CVD method such as a low-pressure plasma CVD method and a thermal CVD method or a PVD method such as a vacuum vapor deposition method and a sputtering vapor deposition method is effected (e.g., refer to JP05-234919A and JP11-054432A), and a method wherein an amorphous silicon thin film is formed at a relatively low temperature by a method among various CVD and PVD methods, and thereafter a heat treatment at about 800° C. is effected or a long-time heat treatment at about 600° C. is effected on the amorphous silicon thin film as a post-treatment (refer to JP05-218368A).

A method in which an amorphous silicon film is crystallized by subjecting the film to a laser annealing process is also known (for example, refer to JP08-124852A, JP2005-197656A, JP2004-253646A).

In addition, formation of a polycrystalline silicon thin film by a catalytic CVD method at a relatively low temperature is also suggested (Jpn. J. Appl. Phys. Vol. 37 (1998) pp. 3175 to 3187 Part 1, No. 6A, June 1998).
Patent document 1: JP2001-313257A
Patent document 2: JP05-234919A
Patent document 3: JP11-054432A
Patent document 4: JP05-218368A
Patent document 5: JP08-124852A
Patent document 6: JP2005-197656A
Patent document 7: JP2004-253646A
Non-patent document 1:
   Jpn. J. Appl. Phys. Vol. 37 (1998) pp. 3175 to 3187 Part 1, No. 6A, June 1998

### DISCLOSURE OF THE INVENTION

### Objects To Be Achieved By the Invention

In the methods for forming crystalline silicon thin films, however, when the substrate is to be exposed to a high temperature, it is necessary to employ, as a substrate for film deposition, a substrate which is resistant to a high temperature and thus is expensive, and it is difficult to form the crystalline silicon thin film on an inexpensive glass substrate having a low melting point (having a heat-resistant temperature not exceeding 500° C.). Therefore, the cost of the substrate disadvantageously increases the producing cost of the crystalline silicon thin films such as polycrystalline silicon thin films.

In the case where the laser annealing is employed, a crystalline silicon thin film can be obtained with a relatively low temperature. In this case, however, a laser irradiation step is required, and laser beams of an extremely high energy density must be emitted. Therefore the producing cost of the crystalline silicon thin film is likewise high also in this case.

A polycrystalline silicon thin film can be obtained at a relatively low temperature by the catalytic CVD method.

By the way, in forming a film onto a deposition target substrate by the CVD method and others, it is preferable to form a high-quality film on the deposition target substrate by carrying out brief etching cleaning of the film, which may be formed also on the wall of the deposition chamber, by gas plasma for cleaning prior to the formation of the film on the next substrate or regularly to suppress the influence of the film on the wall of the deposition chamber. Accordingly, also in the formation of a polycrystalline silicon thin film by the catalytic CVD method, it is preferable to briefly remove the film on the wall of the deposition chamber by plasma etching cleaning (as a typical example, etching cleaning by NF₃ gas plasma).

However, in the formation of a polycrystalline silicon thin film by the catalytic CVD method, it is difficult to carry out plasma cleaning of the film on the wall of the deposition chamber since it results in a damage to a catalyst by the plasma of the gas for cleaning. Accordingly, the cost for maintaining a catalytic CVD apparatus is proportionally increased, and the production cost of the polycrystalline silicon thin film is thus increased.

Moreover, if a polycrystalline silicon film is formed as a semiconductor layer on the gate insulating film by this catalytic CVD method, for example, to be used for manufacturing a thin film transistor, uncombined dangling bonds of silicon and other numerous defects occur at the interface between the gate insulating film and the polycrystalline silicon film, and a leakage current is increased due to such defects.

A first object of the present invention is to provide a method for forming a silicon thin film by a plasma CVD method which can form a crystalline silicon thin film at a relatively low temperature, economically and productively.

A second object of the present invention is to provide a method for forming a silicon thin film which can achieve the above first object and can produce a substrate for a thin film transistor whose leakage current is kept to a low level.

### Means For Achieving the Objects

The present invention provides a first method for forming a silicon thin film described below to achieve the first object.

### (1) First Method for Forming Silicon Thin Film

A method for forming a silicon thin film in which a crystalline silicon thin film is formed on a substrate disposed in a deposition chamber by a plasma CVD method, the method comprising

a hydrogen bonding step in which plasma of a gas for a hydrogen bonding process containing hydrogen is formed in the deposition chamber prior to forming a crystalline silicon thin film on the substrate to expose a film formation target substrate face to the plasma and cause hydrogen to bond onto the substrate face, and

a silicon thin film formation step in which plasma of a gas for forming crystalline silicon thin film containing a silane-based gas is formed in the deposition chamber after the hydrogen bonding step and a crystalline silicon thin film is formed on the substrate face which has been subjected to the hydrogen bonding process in the plasma.

The present invention provides a second method for forming a silicon thin film described below to achieve the second object.

### (2) Second Method for Forming Silicon Thin Film

The method for forming a silicon thin film according to the first method for forming a silicon thin film, wherein a substrate in which a film formation target face is a face of a gate insulating film for thin film transistor formed on the substrate body is employed as the substrate.

According to the first and second methods for forming a silicon thin film of the present invention, a hydrogen bonding step in which hydrogen is caused to bond onto the film formation target substrate face is carried out prior to forming the crystalline silicon thin film on the substrate so that hydrogen is present on the substrate face. Therefore, a crystalline silicon thin film can be formed readily in the following silicon thin film formation step, suppressing the generation of amorphous silicon at the interface between the crystalline silicon thin film and the substrate.

The first and second methods for forming a silicon thin film according to the present invention are methods for forming a silicon thin film by the plasma CVD method, in which the film can be formed at a relatively low temperature. For this reason, the methods enable forming a crystalline silicon thin film on a relatively inexpensive substrate, for example, a low-melting point glass substrate (heat-resistant temperature: 500° C. or lower), and allow crystalline silicon thin films to be formed proportionally economically.

Moreover, since laser irradiation by a costly laser irradiation apparatus and other equipment such as a catalyst and a heater for the same are not necessary, a crystalline silicon thin film can be formed economically also in this term. Since, if required, the film formed on the wall of the deposition chamber can be readily removed by, for example, etching cleaning with NF₃ gas plasma, a high-quality crystalline silicon thin film can be formed economically by keeping the cost for maintaining the film formation apparatus to a proportionally low level.

Therefore, according to the first and second methods for forming a silicon thin film of the present invention, a crystalline silicon thin film can be formed at a relatively low temperature, economically and productively.

According to the second method for forming a silicon thin film of the present invention, a substrate in which the film formation target face is a face of a gate insulating film for thin film transistor formed on the substrate body is employed as the substrate, and a hydrogen bonding step in which hydrogen is caused to bond on the gate insulating film face is carried out prior to forming a crystalline silicon thin film so that hydrogen is present on the face, and therefore a crystalline silicon thin film can be formed readily in the following silicon thin film formation step in a state that defects such as uncombined dangling bonds of silicon at the interface between the gate insulating film and the crystalline silicon thin film are suppressed and generation of amorphous silicon is suppressed. Therefore, a substrate for thin film transistor which is suitable for obtaining a thin film transistor having proportionally high electron mobility and low leakage current can be obtained.

In the second method for forming a silicon thin film, since the hydrogen bonding step is carried out so that hydrogen is present on the substrate face, a crystalline silicon thin film is formed in a state that generation of amorphous silicon at the interface between the crystalline silicon thin film and the substrate is suppressed in the following silicon thin film formation step, and a nitrogen-containing gate insulating film may be employed as the gate insulating film herein. By employing this, in a case where a finally obtained substrate on which a crystalline silicon thin film is formed is used for production of a thin film transistor, a crystalline silicon thin film can be formed while allowing generation of silicon having an amorphousness suitable for improving characteristics relating to OFF-current in the thin film transistor.

Examples of the gate insulating film for thin film transistor include silicon oxide (SiO₂) film, nitrogen-containing gate insulating films, among others.

Examples of the nitrogen-containing gate insulating films include SiON films and SiNₓ films.

In any case, in the second method for forming a crystalline silicon thin film, the period of time for the hydrogen bonding process in the hydrogen bonding step is desirably 60 seconds or shorter. If the period of time is longer than 60 seconds, the amount of hydrogen bonded onto the substrate face is increased, which makes the amorphous silicon layer too thin or allows no layer to be formed, and therefore prevents improvement in the characteristics relating to the OFF-current in the transistor. If the hydrogen bonding treating time is too short, the hydrogen bonding process becomes insufficient, and therefore the amorphous silicon layer becomes too thick, lowering the electron mobility of the transistor. The lower limit of the hydrogen bonding treating time varies depending on the conditions of the gas used and others, but may be in general about 30 seconds or longer.

The thickness of the amorphous silicon layer for improving the characteristics relating to the OFF-current in the transistor may be, for example, 1 nm to 10 nm, and more preferably 1 nm to 5 nm.

As for both the first and second methods for forming a crystalline silicon thin film according to the present invention, the following can be mentioned: Initially, typical examples of the crystalline silicon thin films include polycrystalline silicon thin films.

Examples of gases for hydrogen bonding process used in the hydrogen bonding step include hydrogen gas, mixtures of hydrogen gas and an inert gas (Ar gas, etc.), mixtures of hydrogen gas and a silane-based gas [for example, monosilane (SiH₄) gas] and an inert gas, among others.

When a gas containing a silane-based gas such as SiH₄ gas is employed in addition to hydrogen gas, as the gas for hydrogen bonding process, the amount of the silane-based gas in the gas for hydrogen bonding process can be such an amount that can form a nucleus on which crystalline silicon grows in the silicon thin film formation step to follow. However, in any case, when a gas containing a silane-based gas is employed, the amount of the silane-based gas is adjusted to be such that a silicon film is not formed on the substrate.

The silicon thin film formation step may be initiated after the deposition chamber is evacuated temporarily after the hydrogen bonding step, but the step may be conducted without carrying out evacuation by introducing gas for forming crystalline silicon film containing a silane-based gas into the deposition chamber following the hydrogen bonding step.

Examples of gases for forming a crystalline silicon film containing a silane-based gas used in the silicon thin film formation step include silane-based gases, and mixtures of silane-based gases and hydrogen gas. In any case, the amount of the silane-based gas in the gas for forming a crystalline silicon film is adjusted to such an amount that can form a crystalline silicon thin film.

Examples of the silane-based gas which may be used in the hydrogen bonding step and the silane-based gas used in the silicon thin film formation step include monosilane (SiH₄) gas, disilane (Si₂H₆) gas and other gases, among which SiH₄ gas is a typical example.

The hydrogen bonding step is preferably carried out with a plasma potential of 30 V or lower. The plasma potential in the hydrogen bonding step is related to ionic energy. When the plasma potential is higher than 30 V, growth of silicon crystals becomes difficult due to ion bombardment. The lower limit of the plasma potential can be, for example, generally about 10 V or higher for the purpose of maintaining the plasma.

The hydrogen bonding step is desirably carried out with the electron density in the plasma of the gas for hydrogen bonding process of 1×10¹⁰ electrons/cm³ or more.

The electron density of the plasma in the hydrogen bonding step is related to the amount of hydrogen bonded onto the film formation target face of the deposition target substrate, and when the electron density is lower than 1×10¹⁰ electrons/cm³, growth of silicon crystals becomes difficult.

The upper limit of the electron density may be, for example, about 1×10¹² electrons/cm³ or lower in general in order to suppress damages to the substrate and formed film by ions, and for the reason that in general, increasing the electron density itself any more becomes difficult.

The hydrogen bonding step is preferably carried out with the electron temperature of the plasma of the gas for hydrogen bonding process of 2.5 eV or lower.

The electron temperature of the plasma in the hydrogen bonding step is related to the number of hydrogen ions produced in the plasma, and when the electron temperature is higher than 2.5 eV, the amount of hydrogen ions becomes excessive, whereby damage caused at the interface between a silicon film formed later and the deposition target substrate is increased and the crystallizability of the silicon film is lowered. The lower limit of the electron temperature may be, for example, about 1 eV or higher in general, assuming that the plasma is maintained.

In the hydrogen bonding step,

the plasma potential can be controlled by, for example, adjusting the gas pressure in the deposition chamber. The electron density in the plasma can be controlled by, for example, adjusting the magnitude of the electric power applied for generating plasma.

The electron temperature of the plasma can be controlled by, for example, adjusting the gas pressure and magnitude of the electric power.

Among these adjustable elements, the gas pressure in the deposition chamber must fall within such a range that allows the hydrogen bonding process, which is, for example, about 1 mTorr to 10 mTorr (about 0.13 Pa to 1.33 Pa).

If the pressure is higher than 10 mTorr (about 1.33 Pa), hydrogen ions collide with other particles in the plasma containing hydrogen ions and are prevented from reaching the substrate. If the pressure is lower than 1 mTorr (about 0.13 Pa), maintaining the plasma becomes difficult.

In the silicon thin film formation step, the gas pressure in the deposition chamber may be adjusted to fall within such a range that allows formation of a crystalline silicon thin film, and may be about 0.13 Pa to 6.65 Pa in general. If the pressure is higher than 6.65 Pa, a decrease in the plasma density lowers the crystallizability of silicon.

If the pressure is lower than 0.13 Pa, maintaining the plasma becomes difficult.

The gas pressure in the deposition chamber in the silicon thin film formation step may be also similar to that in the deposition chamber in the hydrogen bonding step.

Formation of the gas plasma in the hydrogen bonding step and the silicon thin film formation step can be conducted by placing parallel plate electrodes inside the deposition chamber and applying high-frequency power to the electrodes, by disposing an inductive coupled antenna inside or outside the deposition chamber and applying high-frequency power to the antenna, or by various other methods. The plasma in the hydrogen bonding step and the silicon thin film formation step may be formed by applying high-frequency power to the inductive coupled antenna placed in the deposition chamber in terms that the input electric power can be efficiently utilized so that a film can be formed on a substrate having a relatively large area.

### Effect of the Invention

As described above, the present invention can provide a method for forming a silicon thin film by a plasma CVD method which can form a crystalline silicon thin film relatively at a low temperature, economically and productively.

The present invention can also provide a method for forming a silicon thin film having such advantages, by which a substrate for thin film transistor with a lowered leakage current can be obtained.

### BRIEF DESCRIPTION OF THE DRAWINGS

FIG. 1 shows an example of a thin film formation apparatus which can be used in the method for forming a polycrystalline silicon thin film.

FIG. 2 shows the results of laser Raman spectroscopic analysis of the silicon film formed in Example 1 and Comparative Example 1.

FIG. 3A is a schematic diagram of a cross section of an amorphous silicon layer and a polycrystalline silicon film on a gate insulating film obtained in Example 2.

FIG. 3B is a schematic diagram of a cross section of a polycrystalline silicon film on a gate insulating film obtained in Example 1.

### DESCRIPTION OF THE SYMBOLS

1 Deposition chamber
11 Top wall of deposition chamber 1
111 Electrical insulation member provided on top wall 11
2 Substrate holder
21 Heater
3 Inductive coupled antenna
31, 32 Ends of antenna 3
4 High-frequency power source
41 Matching box
5 Exhaust pump
51 Conductance valve
6 Hydrogen gas supply unit
7 Monosilane gas supply unit
10 Plasma,diagnosis apparatus
10a Langmuir probe
10b Plasma diagnosing portion
100 Pressure gage

### BEST MODE FOR IMPLEMENTING THE INVENTION

Embodiments of the present invention will be described below with reference to drawings.

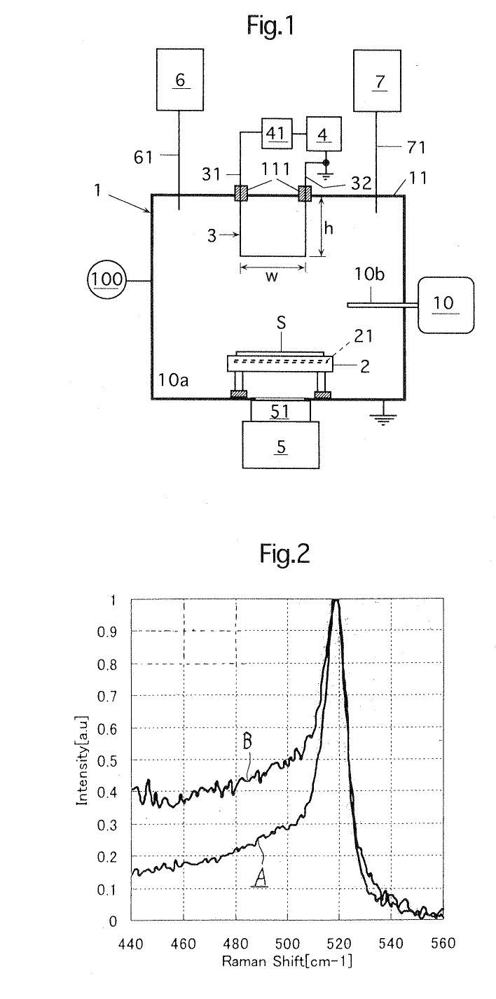

FIG. 1 schematically shows the constitution of an example of a thin film formation apparatus which can be used for carrying out the method for forming a crystalline silicon thin film (polycrystalline silicon thin film in this example) according to the present invention.

The thin film formation apparatus shown in FIG. 1 includes a deposition chamber 1. A holder 2 which retains a deposition target substrate S is placed in a lower part of the deposition chamber 1. The holder 2 has integrated therein a heater 21 which can heat the substrate S retained by the holder.

An antenna 3 of inductive coupling type is disposed in a region opposing the holder 2 in an upper part of the deposition chamber 1. The antenna 3 is in the shape of an inverted gate, and its both ends 31, 32 are extending to the outside of the deposition chamber 1 through an insulation member 111 provided on the top wall 11 of the deposition chamber 1.

An output-variable high-frequency power source 4 is connected to the end 31 of the antenna projecting to the outside of the deposition chamber via a matching box 41. The other end 32 of the antenna is grounded. The frequency of high-frequency power of the power source 4 used herein is, 13.56 MHz, but is not limited to this value.

An exhaust pump 5 is connected to the deposition chamber 1 via an exhaust amount adjustment valve (conductance valve in this example) 51. Furthermore, a hydrogen gas supply unit 6 is connected to the chamber via a gas inlet pipe 61, and a monosilane (SiH₄) gas supply unit 7 is connected to the chamber via a gas inlet pipe 71. Each of the gas supply units 6 and 7 includes a massflow controller for adjusting the amount of the gas supplied into the deposition chamber, a gas source and other components.

The holder 2 is set to have a ground potential via the deposition chamber 1.

A plasma diagnosis device 10 using a Langmuir probe and a pressure gage 100 are provided for the deposition chamber 1. The plasma diagnosis device 10 comprises a Langmur probe 10a inserted into the deposition chamber 1, and can determine a plasma potential and the electron density and electron temperature in the plasma based on the plasma information obtained by the probe. The pressure inside the deposition chamber can be measured by the pressure gage 100.

According to the thin film formation apparatus already described, a polycrystalline silicon thin film can be formed on the substrate S, e.g., in the following manner. In forming a polycrystalline silicon thin film, a hydrogen bonding step in which hydrogen is caused to bond onto a film formation target face of the substrate S is carried out, and subsequently a silicon thin film formation step in which a polycrystalline silicon thin film is formed on the substrate face which has been subjected to the hydrogen bonding process is carried out. These steps will be described below.

<Hydrogen Bonding Step>

The deposition target substrate S is retained on the holder 2 in the deposition chamber 1; the substrate is heated, if necessary, by the heater 21; and the exhaust pump 5 is operated to evacuate the deposition chamber until the pressure inside the chamber becomes lower than the pressure for the hydrogen bonding process. Subsequently, hydrogen gas is introduced into the deposition chamber 1 from the gas supply unit 6 and SiH₄ gas is introduced from the gas supply unit 7 at predetermined rates, and high-frequency power is supplied to the antenna 3 from the output-variable high-frequency power source 4 via the matching box 41 while the pressure inside the deposition chamber is adjusted to the pressure for the hydrogen bonding process by the conductance valve 51.

Accordingly, high-frequency power is applied to the gas for hydrogen bonding process containing the hydrogen gas in the deposition chamber from the antenna, whereby the gas is excited at a high frequency to generate inductively coupled plasma, and hydrogen is caused to bond onto the film formation target substrate face of the substrate S by the plasma irradiation.

This hydrogen bonding process is carried out under the following conditions: the substrate temperature is selected and determined from the range of 150° C. to 400° C.; the pressure inside the deposition chamber from the range of 1 mTorr to 10 mTorr (about 0.13 Pa to about 1.33 Pa); the ratio of the supply flow rates of the gases introduced into the deposition chamber 1 (amount of hydrogen gas [sccm]/amount of SiH₄ gas [sccm]) from the range of 1 to 500; and the high-frequency power density in the deposition chamber from the range of 5 mW/cm³ to 50 mW/cm³; furthermore, the plasma potential during the hydrogen bonding process is maintained to 30 V or lower but 10 V or higher; the electron density in the plasma within the range of 1×10¹⁰ electrons/cm³ or higher but 1×10¹² electrons/cm³ or more; the electron temperature of the plasma to 2.5 eV or lower but 1 eV or higher; and the process time is 30 seconds or more and its upper limit is, for example, 60 seconds or less.

<Silicon Thin Film Formation Step>

When the hydrogen bonding process is completed in this manner, hydrogen gas and SiH₄ gas are introduced into the deposition chamber 1 from the gas supply units 6 and 7, and the ratio of these gases introduced (amount of hydrogen gas [sccm]/amount of SiH₄ gas [sccm]) is selected from the range of 1 to 100 (however, the amount of SiH₄ gas introduced is lower than that during the hydrogen bonding process) to form a polycrystalline silicon film on the substrate face which has been subjected to the hydrogen bonding process.

Referring further to the ratio of the amounts of the hydrogen gas and the SiH₄ gas, the numerical value itself of (amount of hydrogen gas [sccm]/amount of SiH₄ gas [sccm]) may be the same as that during the hydrogen bonding process, but the amount of the SiH₄ gas introduced is adjusted to be higher than that during the hydrogen bonding process.

The ranges of the substrate temperature, the pressure inside the deposition chamber and the high-frequency power density in the deposition chamber in the silicon thin film formation step are selected from the ranges similar to those in the hydrogen bonding step. Moreover, in the silicon thin film formation step, the plasma potential is maintained to 50 V or lower but 10 V or higher; the electron density in the plasma within the range of 1×10⁹ electrons/cm³ or higher but 1×10¹² electrons/cm³ or lower; and the electron temperature of the plasma to 5 eV or lower but 1 eV or higher.

By subjecting the substrate S to the hydrogen bonding process in such a manner and then to the crystalline silicon thin film formation step, a crystalline silicon thin film can be formed readily in the silicon thin film formation step while defects at the interface between the silicon thin film and the substrate and generation of amorphous silicon are suppressed.

Moreover, since it is a method for forming a silicon thin film by the plasma CVD method and a film can be formed at a relatively low temperature, the method enables forming a crystalline silicon thin film on a relatively inexpensive substrate, for example, a low-melting point glass substrate (heat-resistant temperature: 500° C. or lower), and therefore allows crystalline silicon thin films to be formed proportionally economically.

Since laser irradiation by a costly laser irradiation apparatus and other equipment such as a catalyst and a heater for the same are not necessary, a crystalline silicon thin film can be formed economically also in this term. Since, if required, the film formed on the wall of the deposition chamber can be easily removed by etching cleaning using, for example, NF₃ gas plasma, a high-quality crystalline silicon thin film can be formed economically by keeping the cost for maintaining the film formation apparatus to a proportionally low level.

For these reasons, a crystalline silicon thin film can be formed at a relatively low temperature, economically and productively.

Examples of formation of polycrystalline silicon thin films by the apparatus in FIG. 1, that is, providing of a substrate having a polycrystalline silicon thin film by the apparatus in FIG. 1 will be shown now, together with Comparative Examples (Examples for comparison).

### Example 1

Substrate: Non-alkali glass substrate (heat-resistant temperature: 450° C. or lower) on which a silicon oxide (SiO₂) film is formed.

### a) Hydrogen Bonding Step:

Substrate temperature: 400° C.
Pressure inside the deposition chamber: 5 mTorr (0.67 Pa)
Amount of gas supplied into deposition chamber: H₂ [sccm]/SiH₄ [sccm]=150 [sccm]/1 [sccm]
High-frequency power density in deposition chamber: 20 mW/cm³
Plasma potential: 25 V
Electron density: 3×10¹⁰ electrons/cm³
Electron temperature: 2.4 eV
Process time: 30 seconds

### b) Silicon Thin Film Formation Step

The substrate temperature, pressure inside the deposition chamber and high-frequency power density in the deposition chamber were the same as those in the hydrogen bonding step.
Amount of gas supplied into deposition chamber: H₂ [sccm]/SiH₄ [sccm]=150 [sccm]/20 [sccm]
Plasma potential: 25 V
Electron density: 5×10¹⁰ electrons/cm³
Electron temperature: 2.0 eV

### Comparative Example 1

The substrate is identical to that used in the Example 1.

No hydrogen bonding step was carried out.

<Silicon Thin Film Formation Step>

The substrate temperature, pressure inside the deposition chamber and high-frequency power density in the deposition chamber were the same as those in Example 1.
Amount of gas supplied into deposition chamber: H₂ [sccm]/SiH₄ [sccm]=150 [sccm]/20 [sccm]
Plasma Potential: 60 V
Electron density: 8×10⁹ electrons/cm³
Electron temperature: 2.8 eV

The crystalline silicon thin films formed in Example 1 and Comparative Example 1 were subjected to laser Raman spectroscopic analysis by He—Ne laser.

As shown by line A in FIG. 2, a sharp spectrum appears at the Raman shift of about 520⁻¹ cm in the film of Example 1, while the Raman signal (spectral intensity) of amorphous silicon which appears at the Raman shift of about 480⁻¹ cm is small. This indicates that the film as a whole has a high degree of crystallization.

As shown by line B in FIG. 2, the spectrum appearing at the Raman shift of about 520⁻¹ cm in the film of Comparative Example 1 is wider than that in the film of Example 1, and the Raman signal (spectral intensity) of the amorphous silicon appearing at the Raman shift of about 480⁻¹ cm is greater than that of the film of Example 1. It is therefore understood that the film as a whole has more amorphous silicon and a degree of crystallization lower than that of the film of Example 1.

### Example 2

Substrate: Non-alkali glass substrate (heat-resistant temperature 450° C. or lower) having a nitrogen-containing gate insulating film (silicon nitride (SiN) film) as a gate insulating film for thin film transistor

### a) Hydrogen Bonding Step

Substrate temperature: 300° C.
Pressure inside deposition chamber: 5 mTorr (0.67 Pa)
Amount of gas supplied into deposition chamber: H₂ [sccm]/SiH₄ [sccm]=150 [sccm]/1 [sccm]
High-frequency power density in deposition chamber: 20 mW/cm³
Plasma potential: 25 V
Electron density: 2×10¹⁰ electrons/cm³
Electron temperature: 2.4 eV
Process time: 30 seconds

### b) Silicon Thin Film Formation Step

The substrate temperature, pressure inside the deposition chamber and high-frequency power density in the deposition chamber were the same as those in the hydrogen bonding step.
Amount of gas supplied into deposition chamber: H₂ [sccm]/SiH₄ [sccm]=150 [sccm]/20 [sccm]
Plasma potential: 25 V
Electron density: 5×10¹⁰ electrons/cm³
Electron temperature: 2.0 eV

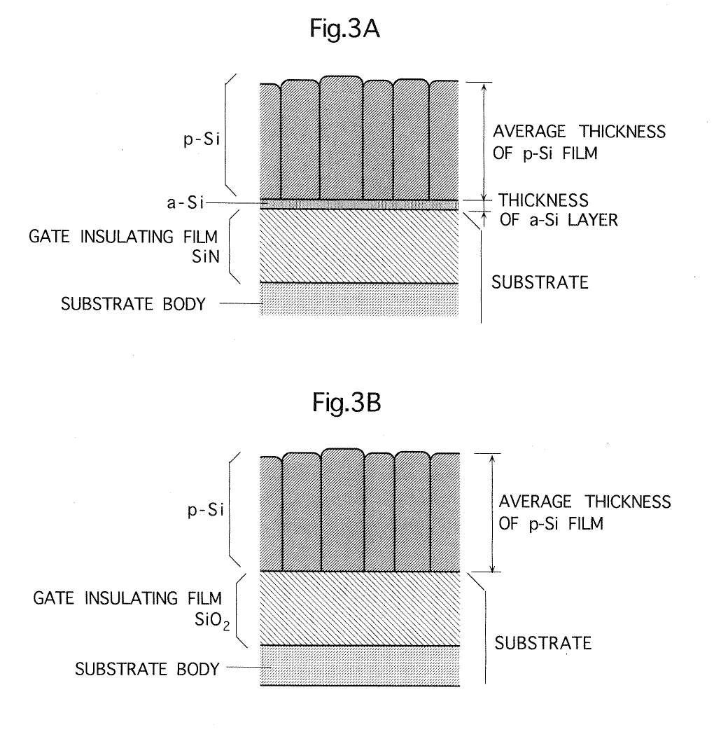

FIG. 3A schematically shows the state of a cross section of the amorphous silicon (a-Si) layer on the gate insulating film (SiN) and the polycrystalline silicon (p-Si) film obtained in Example 2 observed by a transmission electron microscope (TEM), and FIG. 3B schematically shows the state of a cross section of the polycrystalline silicon (p-Si) film on the gate insulating film (SiO₂) obtained in Example 1 observed by a transmission electron microscope (TEM).

The thickness of the amorphous silicon (a-Si) layer on the gate insulating film (SiN) obtained in Example 2 was about 5 nm to 7 nm, and an average thickness of the polycrystalline silicon (p-Si) film was about 50 nm.

An average thickness of the polycrystalline silicon (p-Si) film on the gate insulating film (SiO₂) obtained in Example 1 was about 50 nm.

The crystalline silicon thin film formed in Example 2 was subjected to a laser Raman spectroscopic analysis by using He—Ne laser, whereby it was found that the film had a high crystallizability as a whole as the film of Example 1.

A thin film transistor was formed by using a substrate having a crystalline silicon thin film on each of the gate insulating films provided by Example 2 and Example 1, and the electron mobility and OFF-current of each thin film transistor were determined to obtain the results shown below.
Transistor using substrate of Example 2:

Electron mobility 5 cm²/V·sec.
OFF-current 1×10⁻¹² A
Transistor using substrate of Example 1:

Electron mobility 5 cm²/V·sec.
OFF-current 1×10⁻¹⁰ A

As can be seen from these results, a substrate which can provide a thin film transistor having an electron mobility higher than that of the thin film transistor using an amorphous silicon film as a semiconductor layer by an order of magnitude can be provided by forming either crystalline silicon thin film of Examples 2 and 1.

Moreover, in Example 2 in which a substrate having a gate insulating film containing nitrogen was employed as a substrate, a substrate which can provide a thin film transistor having an OFF-current which is smaller than that in Example 1 in which a substrate having a gate insulating film containing no nitrogen was employed by an order of two magnitudes and having a lowered leakage current can be provided.

### INDUSTRIAL APPLICABILITY

The present invention can be used to form, on the deposition target substrate, a polycrystalline silicon thin film which can be utilized as a material for a TFT (thin film transistor) switch or for producing various kinds of integrated circuits, solar cells and the like as a semiconductor film.

What is claimed is:

1. A method for forming a silicon thin film which forms a crystalline silicon thin film by a plasma CVD method on a substrate disposed in a deposition chamber, the method comprising:
a hydrogen bonding step in which prior to forming the crystalline silicon thin film on the substrate, plasma of a gas for hydrogen bonding process containing hydrogen is formed in the deposition chamber, and a film formation target face of the substrate is exposed to the plasma to cause hydrogen to bond onto the substrate face; and
a silicon thin film formation step in which plasma of a gas for forming crystalline silicon thin film containing a silane-based gas is formed in the deposition chamber after the hydrogen bonding step, and a crystalline silicon thin film is formed on the substrate face which has been subjected to the hydrogen bonding process in the plasma.

2. The method for forming a silicon thin film according to claim 1, wherein a substrate in which the film formation target face is a face of a gate insulating film for thin film transistor formed on the substrate body is employed as said substrate.

3. The method for forming a silicon thin film according to claim 2, wherein the gate insulating film is a nitrogen-containing gate insulating film.

4. The method for forming a silicon thin film according to claim 2 or 3, wherein the hydrogen bonding step is carried out for 60 seconds or shorter.

5. The method for forming a silicon thin film according to any one of claims 1 to 4, wherein a polycrystalline silicon thin film is formed in the silicon thin film formation step.

6. The method for forming a silicon thin film according to any one of claims 1 to 5, wherein the silane-based gas is monosilane (SiH₄) gas.

7. The method for forming a silicon thin film according to any one of claims 1 to 6, wherein the hydrogen bonding step is carried out with a plasma potential of 30 V or lower.

8. The method for forming a silicon thin film according to any one of claims 1 to 7, wherein the hydrogen bonding step is carried out with an electron density in the plasma of the gas for hydrogen bonding process of 1×10¹⁰ electrons/cm³ or higher.

9. The method for forming a silicon thin film according to any one of claims 1 to 8, wherein the hydrogen bonding step is carried out with an electron temperature of the plasma of the gas for hydrogen bonding process of 2.5 eV or lower.

10. The method for forming a silicon thin film according to any one of claims 1 to 9, wherein plasma in the hydrogen bonding step and the silicon thin film formation step is formed by applying high-frequency power to an inductive coupled antenna placed in the deposition chamber.
